(19) United States
(12) Patent Application Publication
(10) Pub. No.: US 2006/0294449 A1
(43) Pub. Date: Dec. 28, 2006

(54) Storage device that transfers block data containing actual data and check code from storage device to host computer

(75) Inventor: Eiji Ikeda, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/227,076

(22) Filed: Sep. 16, 2005

(30) Foreign Application Priority Data
Jun. 27, 2005 (JP) 2005-187105

(51) Int. Cl. G11C 29/00

(52) U.S. Cl. 714/763

(57) ABSTRACT

A method of transferring data from a storage device transfers block data to a host computer, has a first data transfer processing of temporarily holding only actual data by excluding a check code from the block data, and transferring the actual data to the host computer; and a second data transfer processing of transferring data from the storage device to the host computer by controlling the actual data and the check code by segmenting the data for each address. Either the first data transfer processing or the second data transfer processing is selected according to a state of load on the storage device, and the data is transferred from the storage device to the host computer based on the selected data transfer processing.

### CROSS REFERENCE TO RELATED APPLICATION

This application is based upon and claims the benefit of priority from the prior Japanese Patent Application No. 2005-187105, filed on Jun. 27, 2005, the entire contents of which are incorporated herein by reference.

### BACKGROUND OF THE INVENTION

1. Field of the Invention

The present invention relates to a storage device and a method of transferring data from a storage device. More particularly, the present invention relates to a storage device that transfers block data containing actual data and a check code, from the storage device to a host computer, and a method of transferring data from the storage device.

2. Description of the Related Art

In the prior art, a storage device such as a RAID (Redundant Array of Independent (or Inexpensive) Disks) device adds a check code to actual data (i.e., user data) transmitted from a host computer, and writes the data including the check code to the own storage device (for example, a hard disk drive (HDD)), as a write process. The storage device checks the data based on the check code, and transfers only the actual data excluding the check code to the host computer, as a read process. In this case, the block data includes the actual data of 512 bytes, and the check code of 8 bytes, having a total block length of 520 bytes.

Conventionally, as a system for transferring block data from a storage device to a host computer, the following method is known. The storage device first checks the data using a check code, and temporarily stores only actual data excluding the check code into a secondary buffer, and then transfers the actual data to the host computer. The following system is also conventionally considered. The storage device first checks data using a check code in a primary buffer (i.e., a cache memory) in a state that the block data includes the check code. Then, the storage device segments an address of the actual data from the held block data, and transfers the data to the host computer.

Further, in the prior art, there is also a proposal of the following data transfer system as described in Japanese Unexamined Patent Publication No. 2002-351689. According to this data transfer system, a host computer of a data transfer source checks whether data is normally written into a storage device, without interrupting the transfer of actual data. Between the host computer and the storage device, a host adapter and a memory adapter are provided via a system bus. The host adapter has a data buffer, a cyclic redundancy checksum (CRC) check circuit, and a block CRC code to CRC converting circuit. The memory adapter has a data buffer, and a block CRC code generating circuit.

As described above, conventionally, as a system for transferring block data from a storage device to a host computer, there is a known system in which the storage device first checks data using a check code and temporarily stores only actual data excluding the check code into a secondary buffer, and then it transfers the actual data to the host computer. There is also considered a system in which the storage device first checks data using a check code in a primary buffer (i.e., a cache memory) in a state that the block data includes the check code, and then the storage device segments an address of the actual data from the held block data, and transfers the data to the host computer.

In instructing a data transfer to a control chip of a Fibre Channel (FC) and an Internet Small Computer System Interface (ISCSI) device, a data transfer list including a transfer address and a count is used. According to the first data transfer processing method of first temporarily holding only the actual data excluding a check code in the secondary buffer of the storage device, and transferring the actual data to the host computer, one data transfer list is used to assign a unit of data of 512 bytes within the secondary buffer. In this case, the data transfer list has a pair of data values including a transfer address and a count.

On the other hand, according to the second data transfer processing method of transferring data to the host computer by segmenting the address of the actual data from the block data that is temporarily held in the primary buffer in the state of including the check code, data transfer lists are necessary to a number equivalent to the number of blocks in order to segment the data of 520 bytes in the primary buffer in a 512 byte unit. In this case, a plurality of pairs of a transfer address and a count are necessary, and the number of the pairs of data values is the same as the number of transfer blocks.

FC is an interface able to carry out a serial transfer, and this makes it possible to transfer data to the host computer at a high speed and over a large distance. iSCSI is a protocol standard for exchanging data via the Internet Protocol (IP) network, by covering an SCSI command/data in a Transmission Control Protocol/Internet Protocol (TCP/IP) packet.

In the present specification, while a transfer of data read from a storage device to a host computer is mainly explained, the present invention is also applied to writing of data transferred from a host computer into a storage device. Regarding the operation regarding a check code, at the data reading time, a check code is used to check the data, and the check code is removed. At the data writing time, a check code is calculated and added.

The above first data transfer processing and the second data transfer processing have the following characteristics, although there are some differences depending on a hardware configuration such as a capacity of a central processing unit (CPU), a size of a secondary buffer, and the like.

The first data transfer process is advantageous for accessing a large-capacity block data, but has a risk of depleting a secondary buffer when the capacity of the secondary buffer is small. In this case, performance decreases. On the other hand, the second data transfer process is advantageous for accessing small-capacity block data, but tends to load a control chip. While an access to small-capacity block data that is advantageous for the second data transfer processing depends on the capacity of the CPU to a large extent, this block access capacity is about a few KB to a few tens of KB.

As explained above, according to the first data transfer processing, when the capacity of the secondary buffer is small, the secondary buffer is depleted and the performance decreases. According to the second data transfer processing, when the capacity of the block access becomes large, large load is applied to the control chip and the performance decreases. In other words, both the first and the second data transfer processing methods have advantages and disadvantages. When one of these data transfer methods is used, this method has a disadvantage without exception.

In relation to the first data transfer processing to be described later with reference to FIG. 1, a method of increasing the data processing speed is also possible by a check code processing with exclusive hardware. However, when exclusive hardware is used to process the check code, the hardware needs to be changed when the structure of the check code is changed. Therefore, this method is not flexible.

### SUMMARY OF THE INVENTION

An object of the present invention is to provide a storage device capable of suitably transferring block data from a storage device to a host computer, and a method of transferring data from the storage device.

According to the present invention, there is provided a method of transferring data from a storage device that transfers block data to a host computer, comprising a first data transfer processing of temporarily holding only actual data by excluding a check code from the block data, and transferring the actual data to the host computer; and a second data transfer processing of transferring data from the storage device to the host computer by controlling the actual data and the check code by segmenting the data for each address, wherein either the first data transfer processing or the second data transfer processing is selected according to a state of load on the storage device, and the data is transferred from the storage device to the host computer based on the selected data transfer processing.

Either the first data transfer processing or the second data transfer processing may be selected based on a state of the storage device such as a load on a control chip, a data transfer amount during starting of the storage device, a data transfer amount before starting the storage device, and an idle capacity of a secondary buffer that temporarily holds only the actual data excluding the check code from the block data. Either the first data transfer processing or the second data transfer processing may be selected based on a comparison between a predetermined value showing a state of load on the storage device corresponding to the load on the control chip, the data transfer amount during starting of the storage device, the data transfer amount before starting the storage device, and the idle capacity of the secondary buffer, with a threshold value set in advance.

Either the first data transfer processing or the second data transfer processing may be selected such that when the predetermined value showing a state of load on the storage device is smaller than the threshold value set in advance, the first data transfer processing is selected, and when the predetermined value showing a state of load on the storage device is larger than the threshold value set in advance, the second data transfer processing is selected. Either the first data transfer processing or the second data transfer processing may be selected for each host interface port of the storage device.

According to the present invention, there is also provided a storage device that transfers block data from the storage device to a host computer, comprising a storage unit that stores the block data; a primary buffer that temporarily holds the block data having actual data and a check code; a secondary buffer that temporarily holds only the actual data by excluding the check code from the block data; a control chip that controls an interface between the storage device and the host computer; and a selecting unit that selects a first data transfer processing of transferring the actual data held in the secondary buffer to the host computer, and a second data processing of transferring the actual data and the check code to the host computer by controlling the data by segmenting the data for each address, according to a state of load on the storage device.

The selecting unit may select either the first data transfer processing or the second data transfer processing based on a state of the storage device such as a load on a control chip, a data transfer amount during starting of the storage device, a data transfer amount before starting the storage device, and an idle capacity of the secondary buffer.

The selecting unit may select either the first data transfer processing or the second data transfer processing based on a comparison between a predetermined value showing a state of load on the storage device corresponding to the load on the control chip, the data transfer amount during starting of the storage device, the data transfer amount before starting the storage device, and the idle capacity of the secondary buffer, with a threshold value set in advance. The selecting unit may select either the first data transfer processing or the second data transfer processing such that when the predetermined value showing a state of load on the storage device is smaller than the threshold value set in advance, the first data transfer processing is selected, and when the predetermined value showing a state of load on the storage device is larger than the threshold value set in advance, the second data transfer processing is selected.

The selecting unit may select either the first data transfer processing or the second data transfer processing, for each host interface port of the storage device.

Further, according to the present invention, there is provided a data transfer program for transferring data from a storage device to a host computer, comprising a first data transfer processing of temporarily holding only actual data by excluding a check code from the block data, and transferring the actual data to the host computer; and a second data transfer processing of transferring data from the storage device to the host computer by controlling the actual data and the check code by segmenting the data for each address, wherein the program makes a computer execute a selection of either the first data transfer processing or the second data transfer processing according to a state of load on the storage device; and a transfer of the data from the storage device to the host computer based on the selected data transfer processing.

### BRIEF DESCRIPTION OF THE DRAWINGS

The present invention will be more clearly understood from the description of the preferred embodiments as set forth below with reference to the accompanying drawings, wherein:

FIG. 1 is an explanatory diagram of a first data transfer processing of a storage device according to an embodiment of the present invention;

FIG. 2 is an explanatory diagram of a second data transfer processing of a storage device according to an embodiment of the present invention;

FIG. 3 is an explanatory diagram of a concept of a processing carried out by a core deciding unit of the storage device according to an embodiment of the present invention; and

FIG. 4 is an explanatory diagram of a switch between the first data transfer processing and the second data transfer processing of the storage device according to the present invention.

### DESCRIPTION OF THE PREFERRED EMBODIMENTS

A storage device and a method of transferring data from a storage device according to an embodiment of the present invention are explained in detail below with reference to the accompanying drawings.

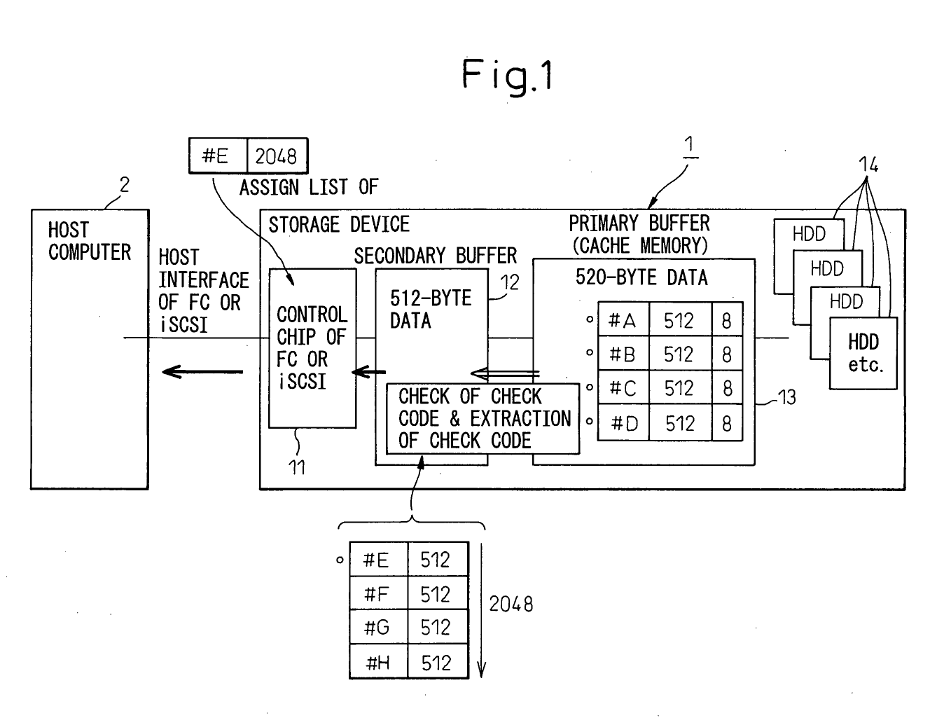

FIG. 1 is an explanatory diagram of a first data transfer processing of the storage device according to an embodiment of the present invention. In FIG. 1, a reference numeral 1 denotes a storage device, and 2 denotes a host computer.

The storage device 1 includes a control chip 11, a secondary buffer 12, a primary buffer (i.e., a cache memory) 13, and hard disk drives (HDD). The control chip 11 is that for an FC or for an iSCSI device. This control chip 11 is used to exchange data between the storage device and the host computer 2 via a host interface of the FC or the iSCSI. While a transfer of data read from the storage device 1 to the host computer 2 is mainly explained below, the present invention is also applied to writing of data transferred from the host computer 2 into the storage device 1.

The primary buffer 13 temporarily holds each block data, read from plural HDDs 14, as 520 bytes. One block of data includes 512-byte actual data and an 8-byte check code.

The secondary buffer 12 holds only the 512-byte data (i.e., only actual data) by excluding the 8-byte check code from the block data. It is needless to mention that a data size of one block of data, and a size of the actual data and a size of the check code in one block data, are not limited to the above sizes, and can be flexibly changed.

The control chip 11 is collectively assigned with 512-byte data from the secondary buffer 12. Specifically, out of 520-byte block data at the addresses #A to #D held in the primary buffer 13, only the 512-byte actual data are stored in the secondary buffer 12. At this time, a check code is checked, and then the check code is removed. Thereafter, when an address #E and a count number 2048 corresponding to four blocks of data are given to the control chip 11, for example, the control chip 11 sequentially transfers the four blocks of actual data of the addresses #A to #D to the host computer 2 via the host interface.

As explained above, in the first data transfer processing of the storage device according to the present embodiment, when the address and a count number in one row are assigned to the control chip 11, the control chip 11 reads plural continuous blocks of data (i.e., actual data).

When the data transferred from the host computer 2 is to be written into the storage device 1, the data (i.e., the actual data) from the host computer 2 is transferred as it is to the secondary buffer 12 via the host interface and the control chip 11. In this case, an address and a count are assigned in only one row to the control chip 11. Thereafter, an 8-bit check code is added to each 512-byte actual data from the secondary buffer 12, and the actual data with the added check code is held in the primary buffer 13. Consequently, the 520-block data including the 512-byte actual data and the 8-byte check code is written into the hard disk drive 14.

As explained above, in the first data transfer processing, when the data transferred from the host computer 2 is to be written into the storage device 1, only the actual data excluding the check data from the block data is temporarily held in the secondary buffer 12, in a similar manner to that when the data read from the storage device 1 is transferred to the host computer 2.

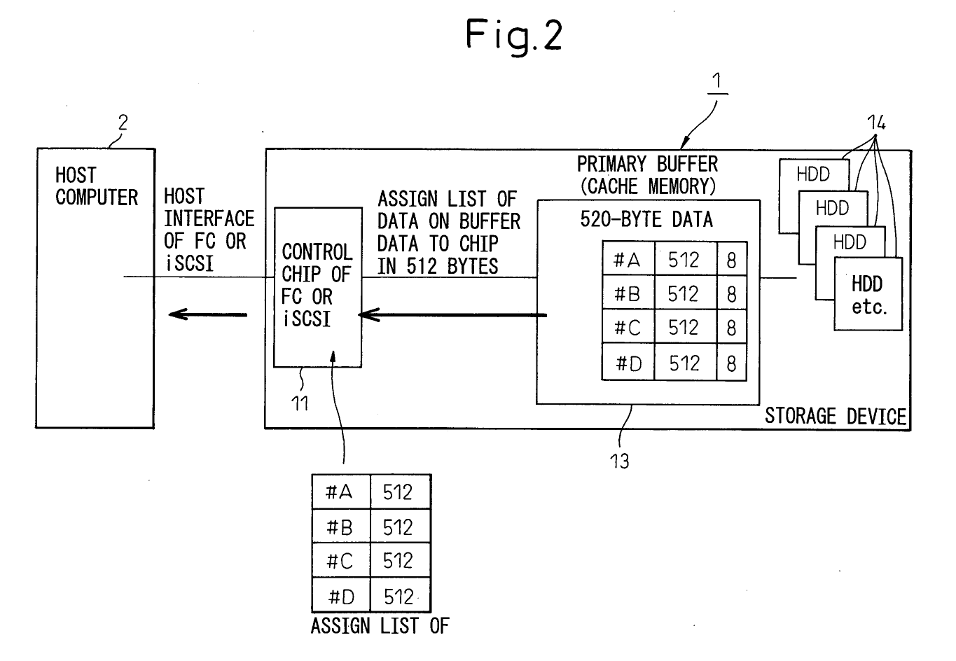

FIG. 2 is an explanatory diagram of the second data transfer processing of the storage device according to an embodiment of the present invention.

As is clear from a comparison between FIG. 1 and FIG. 2, in the second data transfer processing of the storage device according to the present embodiment, the control chip 11 directly reads actual data of each address from the primary buffer 13. Specifically, the 8-byte check data is excluded from each 520-byte block data at the addresses #A to #D held in the primary buffer 13, and the addresses #A to #D and the count number of 512 are given to the control chip 11. With this arrangement, the control chip 11 sequentially transfers the 512-byte actual data of the addresses #A to #D to the host computer 2.

As explained above, in the second data transfer processing of the storage device according to the present embodiment, addresses of the same number of rows as that of the block data are assigned, and plural blocks of data (i.e., actual data) are read.

When the data transferred from the host computer 2 is to be written into the storage device 1, the 512-byte actual data transferred from the host computer 2 are sequentially stored into the primary buffer 13 via the host interface and the control chip 11, by skipping the 8-byte addresses. Thereafter, the skipped 8-byte check codes of addresses corresponding to the 512-byte actual data are embedded into the corresponding data parts. Consequently, 520-byte block data including the 512-byte actual data and the 8-byte check codes are written into the hard disk drive 14.

As explained above, in the second data transfer processing, when the data transferred from the host computer 2 is to be written into the storage device 1, actual data and check codes are controlled by segmenting the address data, instead of holding only the actual data excluding the check data from the block data in the secondary buffer 12, in a similar manner to that when the data read from the storage device 1 is transferred to the host computer 2.

As explained above, the first data transfer processing is advantageous for accessing large-capacity block data, but has a risk of depleting the secondary buffer. In this case, performance decreases. On the other hand, the second data transfer processing is advantageous for accessing small-capacity block data, but tends to apply a load onto the control chip 11. In this case, performance also decreases.

According to the present invention, data transfer between the storage device and the host computer is carried out by employing the advantages of both the first data transfer processing and the second data transfer processing and by compensating for the disadvantages of both processing methods, by dynamically switching the methods within the storage device.

According to the present invention, the first data transfer processing is carried out at the time of accessing large-capacity data, and the second data transfer processing is carried out at the time of accessing small-capacity data. Further, the first data transfer processing and the second data transfer processing are switched over depending on the states of the storage. In other words, both data transfer processing methods are switched over according to the current total access amount of data, the idle capacity or the busy capacity of the secondary buffer, and the capacity of the host interface control chip. With this arrangement, the performance of the data transfer between the storage device and the host computer can be achieved to a maximum extent.

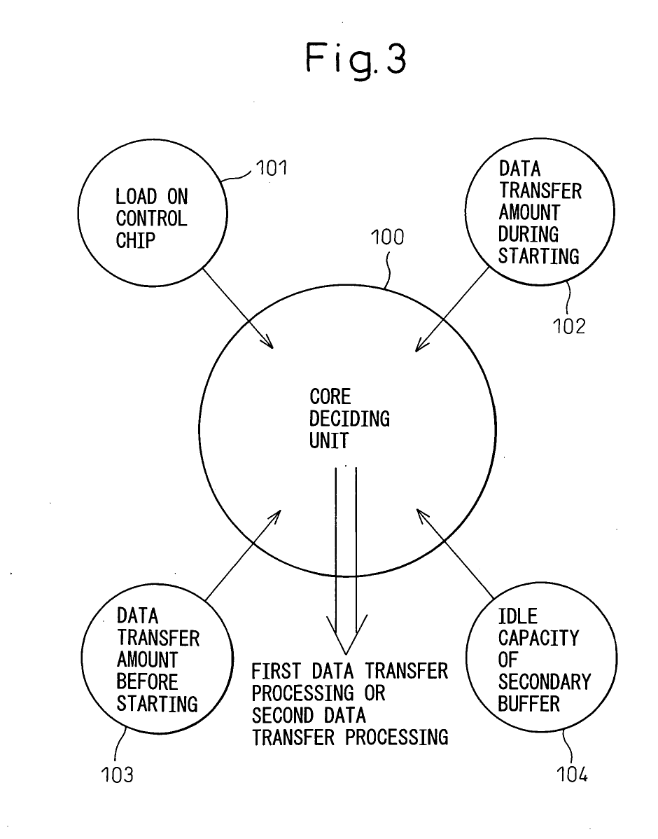

FIG. 3 is an explanatory diagram of the concept of a processing carried out by a core deciding unit of the storage device according to an embodiment of the present invention.

As shown in FIG. 3, a core deciding unit 100 decides to select either the first data transfer processing or the second data transfer processing depending on the load on the storage device, such as a load 101 on the control chip, a data transfer amount 102 during starting of the storage device, a data transfer amount 103 before starting the storage device, and an idle capacity 104 of the secondary buffer.

In other words, immediately before actually executing a data transfer, the four parameters including the load 101 on the control chip, the data transfer amount 102 during starting of the storage device, the data transfer amount 103 before starting the storage device, and the idle capacity 104 of the secondary buffer are input to the core deciding unit 100. The core deciding unit 100 forecasts which one of the first data transfer processing and the second data transfer processing is suitable to carry out a high-speed data transfer, and outputs a result of the decision made. At the same time, new parameters generated based on the selection of the data transfer method are added to the current parameters or fed back, and these parameters are used to make decision next time. After the data transfer is over, the core deciding unit 100 carries out a subtraction, a recalculation, or a feedback based on the parameters. The number of host interface ports of the storage device is not limited to one, and plural host interface ports can be also used. Therefore, the parameters are managed for each host interface port (i.e., for each control chip port).

In selecting the first data transfer processing or the second data transfer processing, the core deciding unit 100 is not simply based on the data transfer amount or the load on the control chip according to one command, but is based on a total data transfer amount according to continuous plural commands and the load on the control chip according to these commands. It is needless to mention that the parameters that are input to the core deciding unit 100 are not limited to the above four parameters which include the load 101 of the control chip, the data transfer amount 102 during starting of the storage device, the data transfer amount 103 before starting the storage device, and the idle capacity 104 of the secondary buffer.

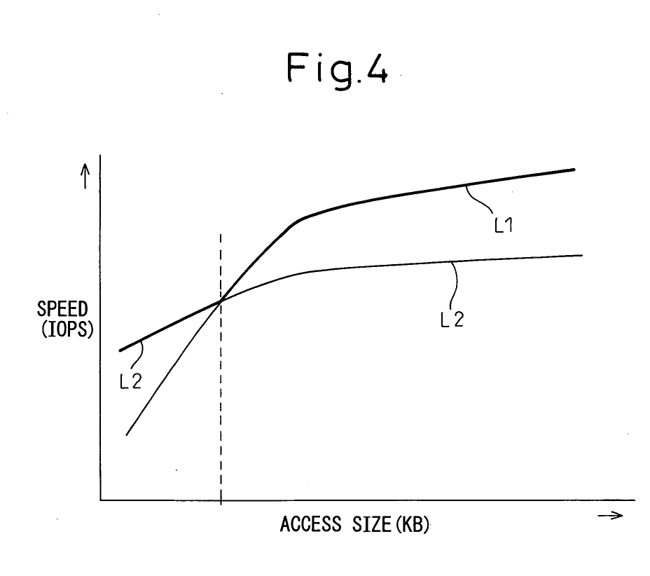

FIG. 4 is an explanatory diagram of a switch between the first data transfer processing and the second data transfer processing of the storage device according to the present invention. In FIG. 4, a reference symbol L1 denotes the first data transfer processing explained with reference to FIG. 1, and a reference symbol L2 denotes the second data transfer processing explained with reference to FIG. 2.

According to the first data transfer processing L1 explained with reference to FIG. 1, data is transferred in two stages. Therefore, assuming that a threshold value (i.e., a certain standard) of a data capacity is a few KB to a few tens of KB or a few hundred KB to a few MB, and when a block access capacity is smaller than this threshold value, the performance of the first data transfer processing L1 is lower than that of the second data transfer processing L2, although this depends on the capacity of the CPU or the like. However, in the first data transfer processing L1, the performance increases stably when data of a capacity exceeding the above threshold value is transferred.

On the other hand, according to the second data transfer processing L2 explained with reference to FIG. 2, data is transferred at one stage. Therefore, for the transfer of small-capacity data, a higher performance than that of the first data transfer processing L1 is obtained. However, in the second data transfer processing L2, the capacity of the control chip comes nearer to a limit when data of a capacity larger than the above threshold value is transferred. The performance does not increase when the access size reaches a certain level. In other words, the performance does not increase when the data transfer capacity exceeds the above threshold value.

As is clear from FIG. 4, in the present invention, the second data transfer processing L2 is used in the area where the data capacity is smaller than the predetermined threshold value, and the first data transfer processing L1 is used in the area where the data capacity is larger than the predetermined threshold value. Based on this arrangement, a performance that cannot be obtained by only one data transfer processing method can be obtained.

The selection of the first data transfer processing or the second data transfer processing is dynamically carried out, according to the state of the storage device such as the load on the chip, the data transfer amount during starting of the storage device, the data transfer amount before starting the storage device, and the idle capacity of the secondary buffer, as explained with reference to FIG. 3. Consequently, it is possible to avoid such a situation where the control chip reaches a limit capacity when a large number of commands are to be executed even when small-capacity data is to be accessed. It is also possible to avoid a situation where the secondary buffer is depleted without being able to fully utilize the capacity of the control chip when the control chip has a large capacity.

The method of transferring data from the storage device according to the present invention can be also provided as firmware (i.e., a program) in a storage device such as a RAID device. This program can be also stored in a flash electrically erasable programmable read-only memory (EEPROM) or other recording medium, and can be provided to a user in this state.

As explained above, according to the present invention, it is possible to provide a storage device capable of suitably transferring block data from the storage device to a host computer, and a method of transferring data from the storage device.

The present invention can be broadly applied to various kinds of storage devices that transfer block data having actual data and a check code to a host computer.

Many different embodiments of the present invention may be constructed without departing from the scope of the present invention, and it should be understood that the present invention is not limited to the specific embodiments described in this specification, except as defined in the appended claims.

What is claimed is:

1. A method of transferring data from a storage device that transfers block data to a host computer, comprising:
a first data transfer processing of temporarily holding only actual data by excluding a check code from the block data, and transferring the actual data to said host computer; and
a second data transfer processing of transferring data from said storage device to said host computer by controlling the actual data and the check code by segmenting the data for each address, wherein:
either the first data transfer processing or the second data transfer processing is selected according to a state of load on said storage device, and the data is transferred from said storage device to said host computer based on the selected data transfer processing.

2. The method of transferring data from a storage device as claimed in claim 1, wherein:
either the first data transfer processing or the second data transfer processing is selected based on a state of said storage device such as a load on a control chip, a data transfer amount during starting of said storage device, a data transfer amount before starting said storage device, and an idle capacity of a secondary buffer that temporarily holds only the actual data excluding the check code from the block data.

3. The method of transferring data from a storage device as claimed in claim 2, wherein:
either the first data transfer processing or the second data transfer processing is selected based on a comparison between a predetermined value showing a state of load on said storage device corresponding to the load on said control chip, the data transfer amount during starting of said storage device, the data transfer amount before starting said storage device, and the idle capacity of said secondary buffer, with a threshold value set in advance.

4. The method of transferring data from a storage device as claimed in claim 3, wherein:
either the first data transfer processing or the second data transfer processing is selected such that when the predetermined value showing a state of load on said storage device is smaller than the threshold value set in advance, the first data transfer processing is selected, and when the predetermined value showing a state of load on said storage device is larger than the threshold value set in advance, the second data transfer processing is selected.

5. The method of transferring data from a storage device as claimed in claim 1, wherein:
either the first data transfer processing or the second data transfer processing is selected for each host interface port of said storage device.

6. A storage device that transfers block data from the storage device to a host computer, comprising:
a storage unit that stores the block data;
a primary buffer that temporarily holds the block data having actual data and a check code;
a secondary buffer that temporarily holds only the actual data by excluding the check code from the block data;
a control chip that controls an interface between the storage device and the host computer; and
a selecting unit that selects a first data transfer processing of transferring the actual data held in the secondary buffer to the host computer, and a second data processing of transferring the actual data and the check code to the host computer by controlling the data by segmenting the data for each address, according to a state of load on the storage device.

7. The storage device as claimed in claim 6, wherein:
the selecting unit selects either the first data transfer processing or the second data transfer processing based on a state of the storage device such as a load on a control chip, a data transfer amount during starting of the storage device, a data transfer amount before starting the storage device, and an idle capacity of the secondary buffer.

8. The storage device as claimed in claim 7, wherein:
the selecting unit selects either the first data transfer processing or the second data transfer processing based on a comparison between a predetermined value showing a state of load on the storage device corresponding to the load on the control chip, the data transfer amount during starting of the storage device, the data transfer amount before starting the storage device, and the idle capacity of the secondary buffer, with a threshold value set in advance.

9. The storage device as claimed in claim 8, wherein:
the selecting unit selects either the first data transfer processing or the second data transfer processing such that when the predetermined value showing a state of load on the storage device is smaller than the threshold value set in advance, the first data transfer processing is selected, and when the predetermined value showing a state of load on the storage device is larger than the threshold value set in advance, the second data transfer processing is selected.

10. The storage device as claimed in claim 6, wherein:
the selecting unit selects either the first data transfer processing or the second data transfer processing, for each host interface port of the storage device.

11. A data transfer program for transferring data from a storage device to a host computer, comprising:
a first data transfer processing of temporarily holding only actual data by excluding a check code from the block data, and transferring the actual data to said host computer; and
a second data transfer processing of transferring data from said storage device to said host computer by controlling the actual data and the check code by segmenting the data for each address, wherein said program makes a computer execute:
a selection of either the first data transfer processing or the second data transfer processing according to a state of load on said storage device; and
a transfer of the data from said storage device to said host computer based on the selected data transfer processing.
